(19) United States
(12) Patent Application Publication
(10) Pub. No.: US 2008/0180921 A1
(43) Pub. Date: Jul. 31, 2008

(54) ELECTRONIC PACKAGE STRUCTURE

(75) Inventors: Da-Jung Chen, Taoyuan County (TW); Chung-Shiun Fang, Tainan County (TW); Bau-Ru Lu, Changhua County (TW); Yi-Cheng Lin, Pingtung County (TW); Chau-Chun Wen, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: CYNTEC CO., LTD., Hsinchu (TW)

(21) Appl. No.: 11/684,645

(22) Filed: Mar. 12, 2007

(30) Foreign Application Priority Data
Jan. 31, 2007 (TW) 96103493

(51) Int. Cl. H05K 7/00

(52) U.S. Cl. 361/729

(57) ABSTRACT

An electronic package structure including a first carrier, at least one first electronic element, and a second electronic element is provided. The first carrier has a first carrying surface and a second carrying surface opposite to each other. The first electronic element is disposed above the first carrying surface and electrically connected to the first carrier. The second electronic element is disposed on the second carrying surface and electrically connected to the first carrier. The volume of the second electronic element is larger than that of the first electronic element.

### CROSS-REFERENCE TO RELATED APPLICATION

This application claims the priority benefit of Taiwan application serial no. 96103493, filed Jan. 31, 2007. All disclosure of the Taiwan application is incorporated herein by reference.

### BACKGROUND OF THE INVENTION

1. Field of the Invention

The present invention relates to a package structure. More particularly, the present invention relates to an electronic package structure.

2. Description of Related Art

Electronic package structures are fabricated through very complicated package processes. The electronic package structures have different electrical performances and heat dissipation capacities. Thus, a designer may select an electronic package structure having suitable electrical performance and heat dissipation capacity according to his/her own requirement.

FIG. 1 is a schematic diagram of a conventional electronic package structure. Referring to FIG. 1, the conventional electronic package structure 100 includes a printed circuit board (PCB) 110 and a plurality of electronic elements 120. The electronic elements 120 are disposed on a surface 112 of the PCB 110 and electrically connected to the PCB 110. The PCB 110 has a plurality of pins 116 extended from another surface 114 of the PCB 110. The PCB 110 may be electrically connected to a next-level electronic apparatus (for example, a mainboard, which is not shown) via these pins 116. However, since all the electronic elements 120 of the electronic package structure 100 are small first-level packages and the surface 112 of the PCB 110 has limited layout area, the volume of the electronic package structure 100 is very large. Besides, the fabricating cost of the electronic package structure 100 is very high for these electronic elements 120 have to be pre-formed through a first-level package process. Moreover, the electronic package structure 100 has to be inserted into the next-level electronic apparatus manually, thus, the electronic package structure 100 and the next-level electronic apparatus cannot be assembled automatically.

Another conventional electronic package structure is provided for resolving foregoing problems. FIG. 2 is a schematic diagram of another conventional electronic package structure. Referring to FIG. 2, the conventional electronic package structure 200 includes a package substrate 210 and a plurality of electronic elements 220. The electronic elements 220 are disposed on a surface 212 of the package substrate 210 and electrically connected to the package substrate 210 through wire bonding technology or surface mount technology. In addition, the electronic package structure 200 may be electrically connected to a next-level electronic apparatus (for example, a mainboard, which is not shown) via solder paste or a plurality of solder balls (not shown).

Compared to the electronic package structure 100, the electronic package structure 200 has following advantages, such as higher element disposition density, smaller volume, simpler fabrication process, lower cost, and the capability of being assembled into a next-level electronic apparatus automatically. However, heat produced during the operation of the electronic package structure 200 can only be conducted to the leads of the next-level electronic apparatus via the conductive vias 214 in the package substrate 210. Accordingly, the heat dissipation capacity of the electronic package structure 200 is unsatisfactory.

Besides, the electronic elements 120 of the electronic package structure 100 are all disposed on a single surface 112 of the PCB 110, and the electronic elements 220 of the electronic package structure 200 are all disposed on a single surface 212 of the package substrate 210. Thus, the efficiency of utilizing space of the PCB 110 in the electronic package structure 100 and the efficiency of utilizing space of the package substrate 210 in the electronic package structure 200 are very low, and the volumes of the electronic package structure 100 and the electronic package structure 200 are very large.

### SUMMARY OF THE INVENTION

Accordingly, the present invention is directed to an electronic package structure of which the efficiency of utilizing internal space is high.

The present invention provides an electronic package structure including a first carrier, at least one first electronic element, and a second electronic element. The first carrier has a first carrying surface and a second carrying surface opposite to each other. The first electronic element is disposed above the first carrying surface and electrically connected to the first carrier. The second electronic element is disposed on the second carrying surface and electrically connected to the first carrier, wherein the volume of the second electronic element is greater than that of the first electronic element.

According to an embodiment of the present invention, the second electronic element may be an energy-storage element. Besides, the second electronic element may be a choke.

According to an embodiment of the present invention, the first carrier may be a leadframe.

According to an embodiment of the present invention, the electronic package structure further includes a second carrier disposed on the first carrying surface and electrically connected to the first carrier. The first electronic element is disposed on the second carrier and electrically connected to the second carrier. In addition, the electronic package structure includes a plurality of first electronic elements, wherein some of the first electronic elements are disposed on the second carrier and electrically connected to the second carrier, and the others are disposed on the first carrying surface and electrically connected to the first carrier. The second carrier may be a wiring board.

According to an embodiment of the present invention, the first electronic element may be a logic control element, a driving element, or a passive element.

According to an embodiment of the present invention, the first electronic element includes a metal-oxide-semiconductor field effect transistor (MOSFET), an insulated gate bipolar transistor (IGBT), or a diode.

According to an embodiment of the present invention, the electronic package structure further includes an encapsulant encapsulating at least the first electronic element, the second electronic element, and part of the first carrier.

As described above, because the second electronic element having larger volume is disposed on the second carrying surface of the first carrier, and the first electronic element having smaller volume is disposed above the first carrying surface of the first carrier, the carrying space of the first carrier can be fully utilized such that the electronic elements in the electronic package structure of the present invention can be disposed in high density.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a conventional electronic package structure.

FIG. 2 is a schematic diagram of another conventional electronic package structure.

FIG. 3A is a schematic side view of an electronic package structure according to a first embodiment of the present invention.

FIG. 3B is a schematic diagram illustrating the possible extensions of at least one lead of a leadframe according to the first embodiment of the present invention.

FIG. 3C is a schematic side view of another electronic package structure according to the first embodiment of the present invention.

FIG. 4 is a schematic side view of an electronic package structure according to a second embodiment of the present invention.

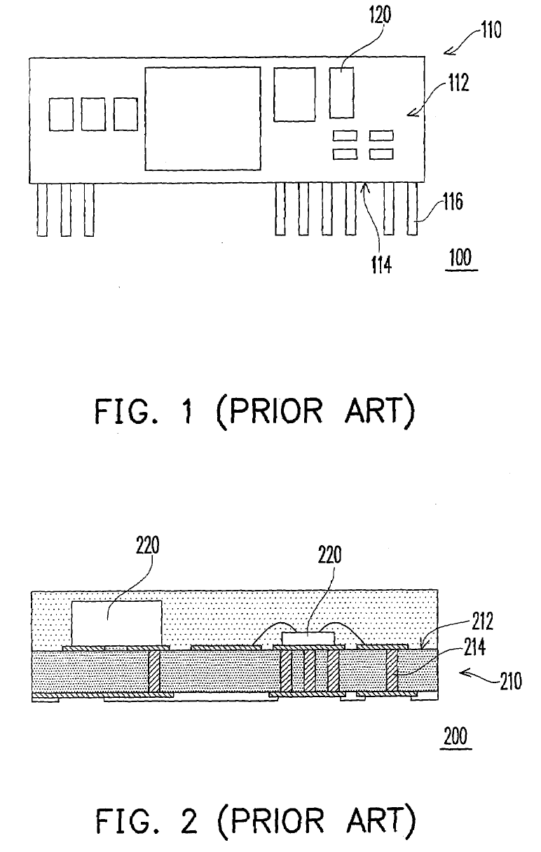

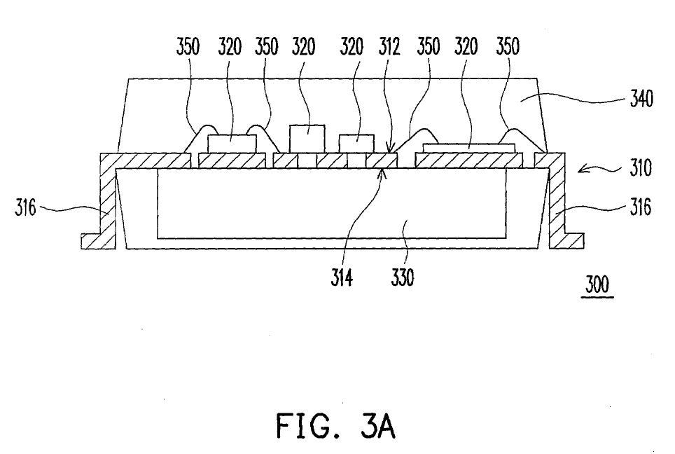

### DESCRIPTION OF EMBODIMENTS

### First Embodiment

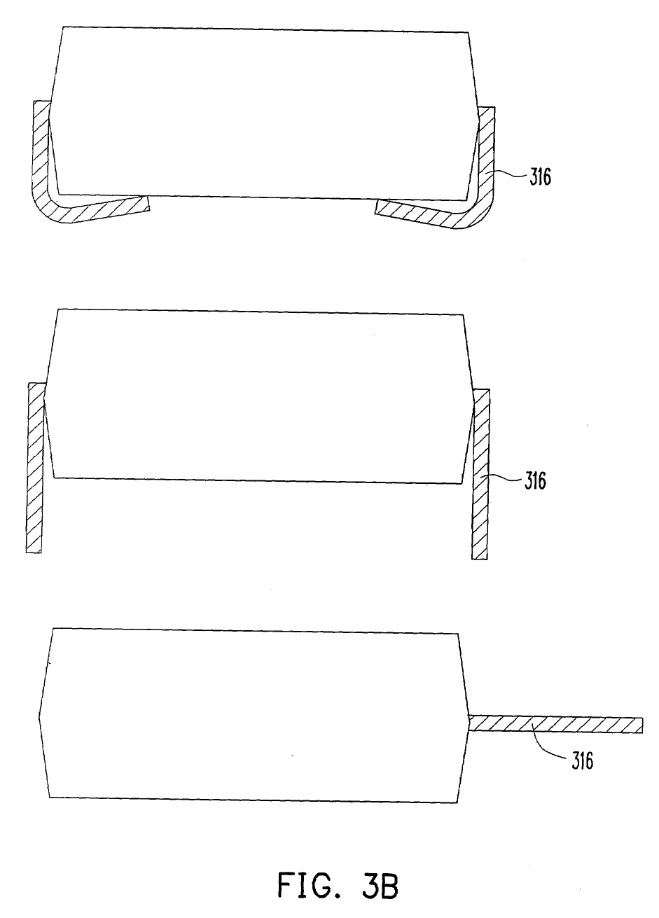

FIG. 3A is a schematic side view of an electronic package structure according to the first embodiment of the present invention. Referring to FIG. 3A, the electronic package structure 300 includes a first carrier 310 (for example, a leadframe), at least one first electronic element 320 (4 first electronic elements 320 are demonstratively illustrated in FIG. 3), and a second electronic element 330. The first carrier 310 has a first carrying surface 312 and a second carrying surface 314 opposite to each other. The first electronic elements 320 are disposed above the first carrying surface 312 and electrically connected to the first carrier 310. The second electronic element 330 is disposed on the second carrying surface 314 and electrically connected to the first carrier 310. The volume of the second electronic element 330 is greater than that of the first electronic element 320.

Since the second electronic element 330 having larger volume can be disposed on the second carrying surface 314 of the first carrier 310, and the first electronic elements 320 having smaller volume can be disposed above the first carrying surface 312 of the first carrier 310, the carrying space of the first carrier 3 10 can be fully utilized such that the electronic elements 320 and 330 in the electronic package structure 300 can be disposed in high density.

In the present embodiment, the second electronic element 330 may be an energy-storage element for storing energy. To be specific, the second electronic element 330 may be a choke which can be considered as an inductive element having large inductance and large volume. Besides, each of the first electronic elements 320 may be a logic control element, a driving element, or a passive element. The passive element may be a capacitor, a low-inductance inductor, or a resistor. Each of the first electronic elements 320 may also be a power element including a MOSFET, an IGBT, or a diode. Moreover, the electronic package structure 300 in the present embodiment is usually applied to a voltage regulator module, a network adapter, or a graphics processing unit.

The electronic package structure 300 in the present embodiment further includes an encapsulant 340. The encapsulant 340 encapsulates at least the first electronic elements 320, the second electronic element 330, and part of the first carrier 310 so that at least one lead 316 (2 leads are demonstratively illustrated in FIG. 3A) of the first carrier 310 (for example, a leadframe) extends out of the encapsulant 340 for electrically connecting a next-level electronic apparatus (for example, a mainboard, which is not shown). It has to be mentioned here that the extension styles of these leads 316 may vary with the designer's requirement; therefore the first embodiment is not intended for restricting the present invention. Please refer to FIG. 3B which schematically illustrates the possible extensions of the leads 316 of the first carrier 310 according to the first embodiment of the present invention.

Furthermore, in the present embodiment, the first electronic elements 320 of the electronic package structure 300 are respectively, from left to right relatively, a logic control element, a capacitor, a resistor, and a power element including a MOSFET. These first electronic elements 320 are all chips. The first electronic element 320 such as the logic control element and the first electronic element 320 such as the power element may be electrically connected to the first carrier 310 respectively through a plurality of bonding wires 350. In other words, the first electronic element 320 such as the logic control element and the first electronic element 320 such as the power element may be electrically connected to the first carrier 310 respectively through wire bonding technology. Certainly, the first electronic element 320 such as the logic control element and the first electronic element 320 such as the power element may also be electrically connected to the first carrier 310 respectively through a plurality of bumps (not shown). In other words, the first electronic element 320 such as the logic control element and the first electronic element 320 such as the power element may be electrically connected to the first carrier 310 respectively through flip chip bonding technology; however, which is not shown in any drawing.

Besides, the first electronic element 320 such as the capacitor and the first electronic element 320 such as the resistor may be electrically connected to the first carrier 310 respectively through solder paste (not shown). In other words, the first electronic element 320 such as the capacitor and the first electronic element 320 such as the resistor may be electrically connected to the first carrier 310 respectively through surface mount technology. It has to be mentioned here that the method for connecting these first electronic elements 320 to the first carrier 310 is determined according to the designer's requirement. Accordingly, the present embodiment is not intended for restricting the present invention.

In addition, the second electronic element 330 may also be a chip and may also be electrically connected to the first carrier 310 through wire bonding technology, surface mount technology, or flip chip bonding technology.

FIG. 3C is a schematic side view of another electronic package structure according to the first embodiment of the present invention. Referring to FIG. 3C, the main difference between the electronic package structure 300′ and the electronic package structure 300 is that the first electronic elements 320′ and the second electronic element 330′ of the electronic package structure 300′ may be chip packages. These first electronic elements 320′ and the second electronic element 330′ which may be chip packages may be electrically connected to the first carrier 310′ through solder paste (not shown) or conductive paste (not shown). In other words, these first electronic elements 320′ and the second electronic element 330′ may be electrically connected to the first carrier 310′ through surface mount technology. It has to be emphasized here that at least one of the first electronic elements 320′ and the second electronic element 330′ of the electronic package structure 300′ may also be chips according to the designer's requirement, namely, as a whole, the electronic package structure 300′ may have electronic elements such as chips and chip packages; however, which is not shown in any drawing.

### Second Embodiment

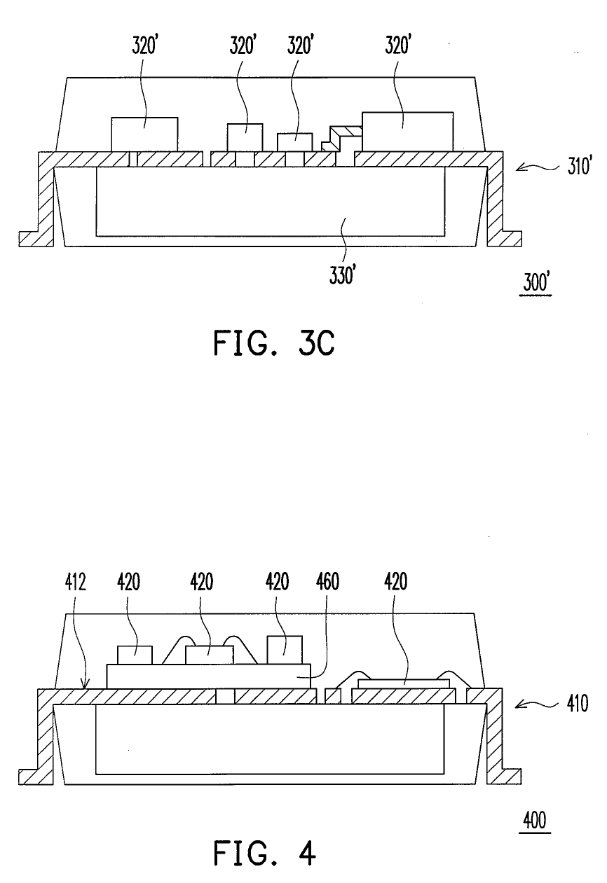

FIG. 4 is a schematic side view of an electronic package structure according to a second embodiment of the present invention. Referring to FIG. 4, the main difference of the electronic package structure 400 in the present embodiment from the electronic package structures 300 and 300′ in the first embodiment is that the electronic package structure 400 further includes a second carrier 460. Some of the first electronic elements 420 are disposed on the second carrier 460 and electrically connected to the second carrier 460. The second carrier 460 is disposed on the first carrying surface 412 of the first carrier 410 and electrically connected to the first carrier 410. The second carrier 460 may be a wiring board.

The second carrier 460, which may be a wiring board, is composed of a plurality of wiring layers (not shown) and a plurality of dielectric layers (not shown) which are stacked together alternatively At least two of the wiring layers are electrically connected to each other via at least one conductive via (not shown). Thus, the internal layout density of the second carrier 460 is usually very high and the internal layout of the second carrier 460 is usually very complicated. It has to be mentioned here that the appearances of the first carrier 410 and the second carrier 460 may vary according to the designer's requirement, therefore the present embodiment is not intended for restricting the present invention.

In overview, the electronic package structure in the present invention has at least following advantages:
1. The second electronic element having larger volume is disposed on a second carrying surface of the first carrier, and the first electronic element having smaller volume is disposed above a first carrying surface of the first carrier, thus, the carrying space of the first carrier can be fully utilized such that these electronic elements in the electronic package structure of the present invention can be disposed in high density.
2. The electronic package structure in the present invention can be electrically connected to a next-level electronic apparatus through surface mount technology, thus, the electronic package structure in the present invention can be automatically assembled into a next-level electronic apparatus. Accordingly, productivity is increased and assembly cost is reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An electronic package structure, comprising:
a first carrier, having a first carrying surface and a second carrying surface opposite to each other;
a plurality of first electronic elements, disposed above the first carrying surface and electrically connected to the first carrier; and
a second electronic element, disposed on the second carrying surface and electrically connected to the first carrier, wherein the volume of the second electronic element is greater than the volume of each of the first electronic elements, the second electronic element is an energy-storage element, and the projection of each of the first electronic elements on the first carrying surface at least overlaps the projection of the second electronic element on the first carrying surface.

2. (canceled)

3. The electronic package structure as claimed in claim 1, wherein the second electronic element is a choke.

4. The electronic package structure as claimed in claim 1, wherein the first carrier is a leadframe, wherein some of the first electronic elements and the second electronic element are directly disposed on the leadframe and directly electrically connected to the leadframe.

5. The electronic package structure as claimed in claim 1 further comprising a second carrier directly disposed on the first carrying surface and electrically connected to the first carrier.

6. The electronic package structure as claimed in claim 5, wherein the first electronic elements are disposed on the second carrier and electrically connected to the second carrier.

7. The electronic package structure as claimed in claim 5, wherein some of the first electronic elements are disposed on the second carrier and electrically connected to the second carrier, and the others are disposed on the first carrying surface and electrically connected to the first carrier.

8. The electronic package structure as claimed in claim 5, wherein the second carrier is a wiring board.

9. The electronic package structure as claimed in claim 1, wherein each of the first electronic elements is a logic control element, a driving element, or a passive element.

10. The electronic package structure as claimed in claim 1, wherein each of the first electronic elements comprises a metal-oxide-semiconductor field effect transistor (MOSFET), an insulated gate bipolar transistor (IGBT), or a diode.

11. The electronic package structure as claimed in claim 1 further comprising an encapsulant, wherein the encapsulant encapsulates at least the first electronic elements, the second electronic element, and part of the first carrier.

12. The electronic package structure as claimed in claim 1, wherein the projection of the second electronic element on the first carrying surface entirely covers the projections of at least two of the first electronic elements.
